(19) United States
(12) Patent Application Publication
(10) Pub. No.: US 2025/0228057 A1
(43) Pub. Date: Jul. 10, 2025

(54) Micro LED Emissive Display Architecture Using Bottom Emission Stack

(71) Applicant: Apple Inc., Cupertino, CA (US)

(72) Inventors: Vaibhav D. Patel, San Jose, CA (US); Stephen P. Bathurst, Lafayette, CA (US); Xia Li, San Jose, CA (US); Waldemar J. Siskens, Palo Alto, CA (US)

(21) Appl. No.: 18/976,802

(22) Filed: Dec. 11, 2024

Related U.S. Application Data
(60) Provisional application No. 63/618,813, filed on Jan. 8, 2024.

(51) Int. Cl. H10H 29/80; H10H 29/37; H10H 29/49; H10H 29/85

(52) U.S. Cl. CPC H10H 29/942; H10H 29/37; H10H 29/49; H10H 29/8506

(57) ABSTRACT

Display structures and methods of fabrication are described. In an embodiment, a display structure includes an array of pixel driver chips embedded in an insulation layer, a redistribution layer (RDL) over and in electrical contact with the array of pixel driver chips, and an array of light emitting diodes (LEDs) over and in electrical contact with the RDL, where the array of LEDs includes different groups of LEDs designed for different wavelength emission spectra, and the top surfaces of the LEDs are coplanar.

### RELATED APPLICATIONS

This application claims the benefit of priority of U.S. Provisional Application No. 63/618,813, filed Jan. 8, 2024, which is herein incorporated by reference.

### BACKGROUND

### Field

Embodiments described herein relate to light emitting structures. More specifically, embodiments relate to micro light emitting diode (LED) based display panels.

### Background Information

State of the art displays for portable electronics, computers, and televisions commonly utilize glass substrates with thin film transistors (TFTs). More recently, it has been proposed to replace the TFT substrate for emissive displays such as those based on organic light emitting diodes (OLEDs) or inorganic semiconductor-based micro LEDs with a substrate including a matrix of pixel driver chips either embedded within or mounted onto the substrate, where each pixel driver chip is to switch and drive one or more LEDs.

### SUMMARY

In some aspects, the techniques described herein relate to display structures and methods of manufacture that employ an “LED first” integration sequence. In an embodiment, a display structure includes an array of pixel driver chips embedded in an insulation layer, a redistribution layer (RDL) over and in electrical contact with the array of pixel driver chips, and an array of light emitting diodes (LEDs) over and in electrical contact with the RDL. The array of LEDs may include a first group of first LEDs designed for a first wavelength emission spectrum, with each first LED including a first top surface, and a second group of second LEDs designed for a second wavelength emission spectrum different from the first wavelength emission spectrum, with each second LEDs including a second top surface. In accordance with embodiments each first top surface is coplanar with each second top surface.

In some embodiments transparent placement structures may be included, for example, to aid in throughput or light extraction. In an embodiment, the display structure includes an array of transparent placement structures onto which top surfaces of the array of LEDs are placed, with each transparent placement structure being characterized as a bank structure including a bank bottom surface, bank sidewalls, and a bank top surface. In some embodiments the bank top surface is characterized by a greater surface roughness than the bank bottom surface for each transparent placement structure. For example, the array of transparent placement structures may be formed on a passivation layer, where the bank top surface for each transparent placement structure is conformal to a roughened bottom surface of the passivation layer.

The manufacture sequences in accordance with embodiments are compatible with both vertical LEDs and horizontal LEDs. The different groups of LEDs can also have different thicknesses, while maintaining coplanarity of their top surfaces. In an exemplary vertical LED display structure, a transparent electrode layer may span over the array of transparent placement structures, where the top surfaces of the array of LEDs are in electrical contact with the transparent electrode layer. For example, the transparent electrode layer may span over the bank bottom surface and the bank sidewalls of each transparent placement structure. Furthermore, the bank bottom surface of each transparent placement structure may be coplanar. In an exemplary horizontal LED display structure, the RDL may include an array of contact via line pairs in electrical contact with the bottom surfaces of the array of LEDs such that each contact via line pair is in electrical contact with a corresponding LED.

The pixel driver chips in accordance with embodiments may also be embedded face up or face down within the display structure. In an embodiment, each pixel driver chip is bonded to the RDL with a plurality of solder bumps. For example, this may be a face down configuration with the contact pads of the pixel driver chips facing the RDL. In an embodiment, each pixel driver chip includes a front side with a plurality of contact pads facing away from the RDL. This may be a face up configuration. In either configuration a plurality of vertical interconnects can extend through an insulation layer within which the pixel driver chips are embedded. For example, these may be used to electrically connect the array of pixel driver chips with the RDL, as well as to electrically connect to other system components.

The RDL in accordance may be fabricated using suitable techniques, including thin film techniques. In an embodiment, the RDL includes a plurality of wiring layers forming a plurality of redistribution lines and a plurality of contact via lines, and a plurality of interlayer dielectric (ILD) layers separating levels of redistribution lines of the plurality of redistribution lines. The plurality of contact line vias may extend through one or more ILD layers of the plurality of ILD layers. For example, a first group of contact via lines may extend through a thickness of at least two ILD layers, through a thickness of at least three ILD layers, or more. In some embodiments thin film fabrication sequences may be utilized so that the contact via lines extend through via openings through the one or more ILD layers and form an outline conforming to the via openings.

The display structures and fabrication sequences are also compatible with hybrid structures in which the RDL additionally includes a thin film transistor (TFT) layer including an array of TFTs coupled with the array of LEDs and the array of pixel driver chips. The TFTs can be suitable transistors and can include a combination of transistors including both low temperature polycrystalline silicon (LTPS) TFTs and oxide TFTs.

### BRIEF DESCRIPTION OF THE DRAWINGS

FIG. 1 is a schematic top view illustration of a display structure in accordance with an embodiment.

FIG. 2 is a schematic top view illustration of a matrix including a pixel driver chip to switch and drive multiple pixels of LEDs in accordance with an embodiment.

FIG. 3 is an isometric view of a mobile telephone in accordance with an embodiment.

FIG. 4 is an isometric view of a tablet computing device in accordance with an embodiment.

FIG. 5 is an isometric view of a wearable device in accordance with an embodiment.

FIG. 6 is an isometric view of a laptop computer in accordance with an embodiment.

FIG. 7 is a system diagram of a portable electronic device in accordance with an embodiment.

FIG. 8 is a schematic cross-sectional side view illustration of a portion of a display structure stack-up accordance with an embodiment.

FIGS. 9A-9G″ are schematic cross-section side view illustrations for a sequence of fabricating a display structure in accordance with an embodiment.

FIG. 10 is a schematic cross-sectional side view illustration of a display structure including back side connections in accordance with an embodiment.

FIG. 11 is a schematic cross-sectional side view illustration of a display structure including an array of TFTs in an RDL in accordance with an embodiment.

### DETAILED DESCRIPTION

Embodiments describe display structures and methods of manufacture that employ an “LED first” integration sequence in which an array of LEDs (including multiple different groups of LEDs designed for different wavelength emission spectra) is first integrated followed by subsequent completion of a redistribution layer (RDL) for electrical routing, and the integration of an array of pixel driver chips. In accordance with embodiments the display structure fabricated using such techniques can align the top surfaces of each LED so that they are coplanar. In some embodiments selective placement structures including an existing planar surface are first fabricated, followed by mass transfer of the LEDs from one or more donor substrates to the selective placement structures. For example, this can be accomplished with a pick and place tool with an array of transfer heads.

In one aspect, embodiments described herein may facilitate emissive light extraction. For example, the planar top surfaces of the LEDs can benefit display Mura effect. Furthermore, a uniform flat and roughened surface can be provided over the planar top surfaces of the LEDs to increase light extraction. Additional structures can also be integrated to enhance light extraction and viewing angle such as distributed Bragg reflector (DBR), or metal routing within the RDL.

In one aspect, the receiving structures (e.g., selective placement structures) and LED transfer sequences can improve total thickness variation (TTV) of the display structures, and thereby overall assembly yield. The scalable architecture is also compatible with both vertical and horizonal LEDs, and topography provided by the selective placement structures can facilitate multi place transfer sequences from a single transfer head array.

In another aspect, the processing sequences described herein facilitate panel level passivation techniques, where key encapsulation structures are formed earlier in the process flow, easing integration challenges such as TTV and topography of the stack-up.

In another aspect, the processing sequences described herein facilitate RDL formation in which contact via lines extend through the thickness of multiple interlayer dielectric (ILD) layers, which can mitigate routing complexity and provide space savings.

In yet another aspect, the processing sequences described herein can avoid thermal budgets by placing the pixel driver chips last in the stack-up. Furthermore, the integration techniques and RDL formation are also compatible with TFT integration for a hybrid TFT and pixel driver chip architecture where the TFT layers can be fabricated prior to pixel driver chip integration, removing a thermal budget constraint for TFT fabrication. In such a configuration the pixel driver chips may provide digital functionality with the TFT layer including local subpixel circuitry to provide analog functionality. Additional sensing dies and chipsets can also be integrated using the processing sequences described herein, including laser, photodiode, readout integrated circuits, and image sensors with wafer level micro-optics.

In yet another aspect, the processing sequences described herein allow for peripheral electronic components such as a display timing controller (TCON), which is typically located off panel, can be attached without using conventional chip on film (COF) techniques, therefore eliminating conventional bend tail further leading to potential border reduction.

In various embodiments, description is made with reference to figures. However, certain embodiments may be practiced without one or more of these specific details, or in combination with other known methods and configurations. In the following description, numerous specific details are set forth, such as specific configurations, dimensions and processes, etc., in order to provide a thorough understanding of the embodiments. In other instances, well-known processes and manufacturing techniques have not been described in particular detail in order to not unnecessarily obscure the embodiments. Reference throughout this specification to “one embodiment” means that a particular feature, structure, configuration, or characteristic described in connection with the embodiment is included in at least one embodiment. Thus, the appearances of the phrase “in one embodiment” in various places throughout this specification are not necessarily referring to the same embodiment. Furthermore, the particular features, structures, configurations, or characteristics may be combined in any suitable manner in one or more embodiments.

The terms “over”, “to”, “between”, “spanning” and “on” as used herein may refer to a relative position of one layer with respect to other layers. One layer “over”, “spanning” or “on” another layer or bonded “to” or in “contact” with another layer may be directly in contact with the other layer or may have one or more intervening layers. One layer “between” layers may be directly in contact with the layers or may have one or more intervening layers.

The terms “micro” device or “micro” LED as used herein may refer to the descriptive size of certain devices or structures in accordance with embodiments. As used herein, the term “micro” is meant to refer to the scale of 1 to 300 μm. For example, each micro LED may have a maximum length or width of 1 to 300 μm, 1 to 100 μm, or less. In some embodiments, the micro LEDs may have a maximum length and width of 20 μm, 10 μm, or 5 μm. However, it is to be appreciated that embodiments of the present invention are not necessarily so limited, and that certain aspects of the embodiments may be applicable to larger, and possibly smaller size scales.

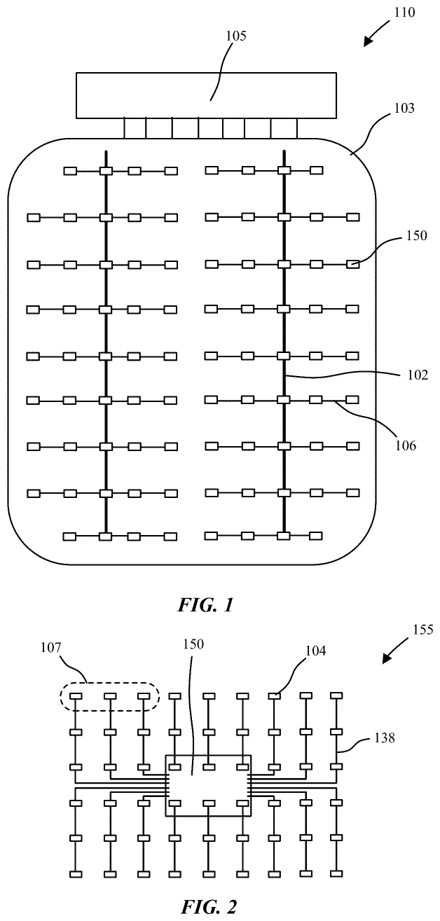

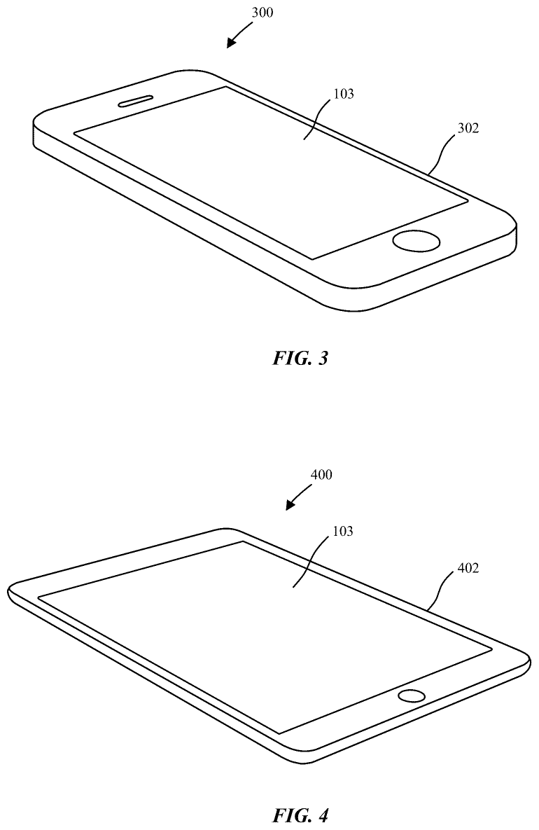

Referring now to FIG. 1 a schematic top view illustration is provided of a display structure 110 including a display panel 103 with an arrangement of pixel driver chips 150 and rounded edges or corners. Further, such display panels 103 can be molded into a curved 3D film contour. FIG. 2 is an example of a local matrix 155 including a pixel driver chip 150 coupled to a micro-matrix of LEDs 104 (e.g. micro LEDs) with redistribution lines 138. Each pixel diver chip 150 may switch and drive multiple pixels 107 of LEDs 104 within the micro-matrix of LEDs 104. This may include either a direct drive approach, where every pin of the pixel driver chip 150 is connected to one LED, or a local passive matrix (LPM) arrangement in which pins of the pixel driver chips 150 can be connected to strings of LEDs as shown in FIG. 2. In an embodiment, this may be an LPM local matrix 155. LPM arrangements in accordance with embodiments may significantly reduce the silicon area associated with the pixel drivers, and the peak panel current. In some embodiments, a TFT layer can also be integrated into local matrix 155 along with the pixel driver chips 150 and LEDs 104.

In accordance with all embodiments described herein the pixel driver chips 150 may be located within the display panel 103 and may be positioned face up (e.g. with terminals facing up towards the LEDs 104), positioned face down (e.g. with terminals facing away from the LEDs), or both (with terminals on both top and bottom sides).

In particular, the arrangement of pixel driver chips 150 in accordance with embodiments can remove the requirement for driver ledges on the edges of a display panel 103. As a result, the display panel 103 may have reduced borders, or zero borders outside of the display area. An external control circuit 105 may be attached with the display panel 103 to supply various control signals, video signals, and power supply voltage to the display panel 103. The control circuit 105 may include a timing controller (TCON). Additional system components can also be connected to the display panel along with the control circuit, such as a host system on chip (SOC), power management integrated circuit (PMIC), level shifters, touch screen controller, additional passives, etc. Generally, the control circuit 105 may be coupled to an edge of the display panel 103, though may also be coupled to a back side of the display panel 103 in accordance with embodiments. Bus columns of global routing lines 102 may extend from the control circuit 105 to supply global signals to the display panel 103. For example, the global routing lines 102 may include at least data clock lines, emission clock lines, and vertical selection token (VST) lines. The global routing lines are coupled to a plurality of “hybrid” pixel driver chips, and together form a backbone of the display. The corresponding backbone hybrid pixel driver chips receive the global signals and then transmit manipulated signals to their corresponding rows of row lines 106 connected to the other pixel driver chips 150 within the same row. For example, the global data clock and emission clock signals may be converted to manipulated signals and transmitted to the row of pixel driver chips 150 along manipulated data clock lines and manipulated emission clock lines. For example, the manipulated signals may include only the necessary information for the particular row.

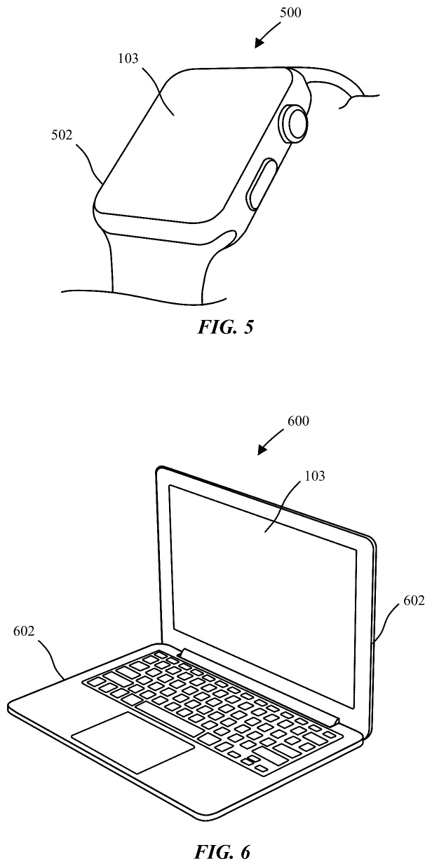

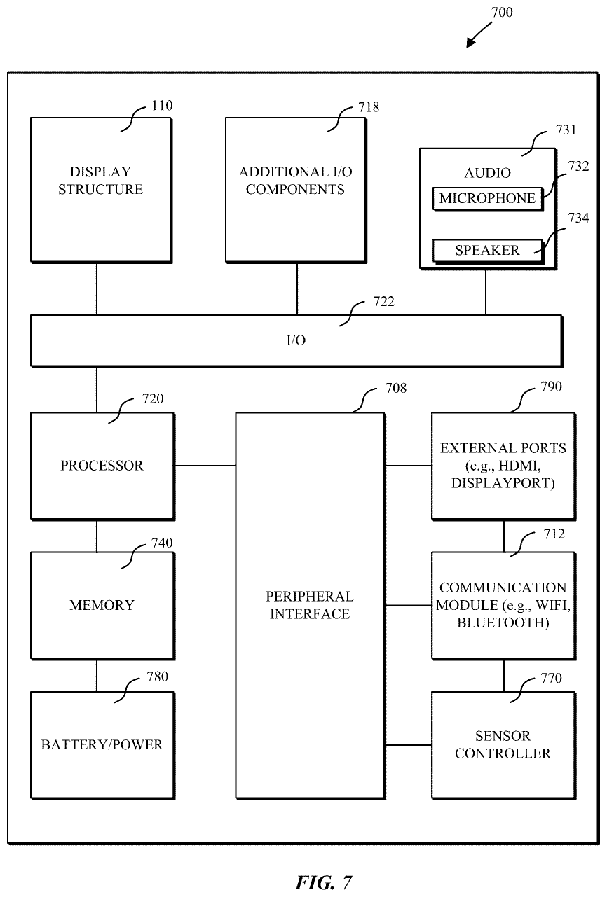

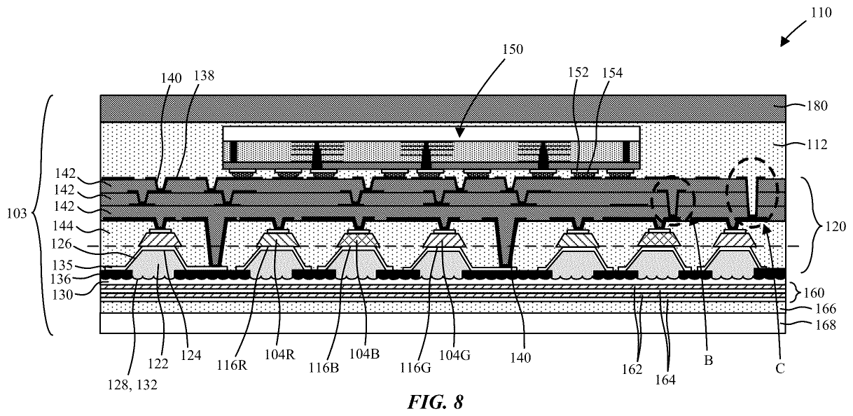

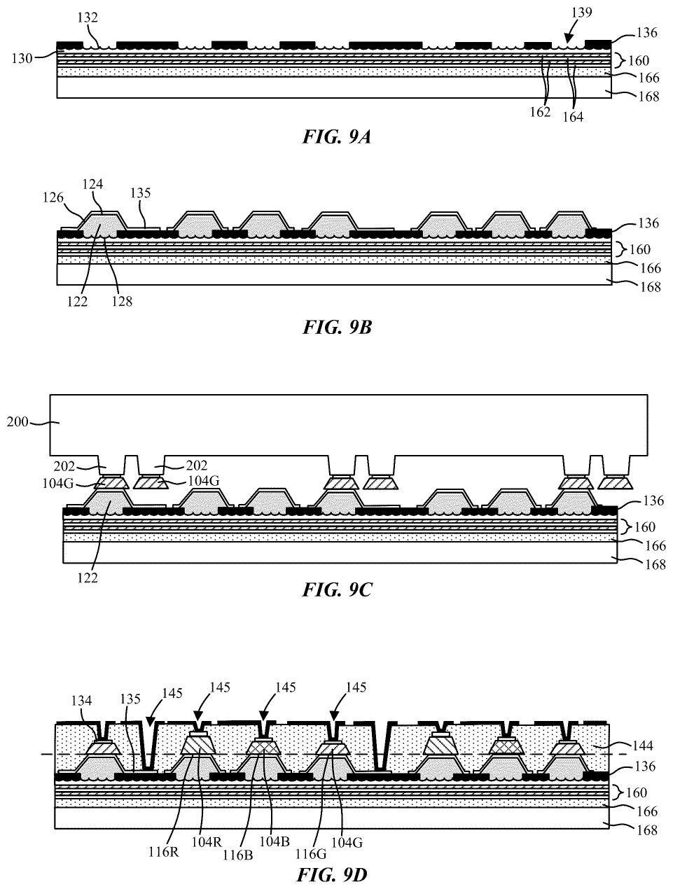

FIGS. 3-6 illustrate various portable electronic systems in which the various embodiments can be implemented. FIG. 3 illustrates an exemplary mobile telephone 300 that includes a display structure including a display panel 103 packaged in a housing 302. FIG. 4 illustrates an exemplary tablet computing device 400 that includes a display structure including a display panel 103 packaged in a housing 402. FIG. 5 illustrates an exemplary wearable device 500 that includes a display structure including a display panel 103 packaged in a housing 502. FIG. 6 illustrates an exemplary laptop computer 600 that includes a display structure including a display panel 103 packaged in a housing 602. In each embodiment, the display structure can have a display panel 103 with a curved three-dimensional (3D) film contour.

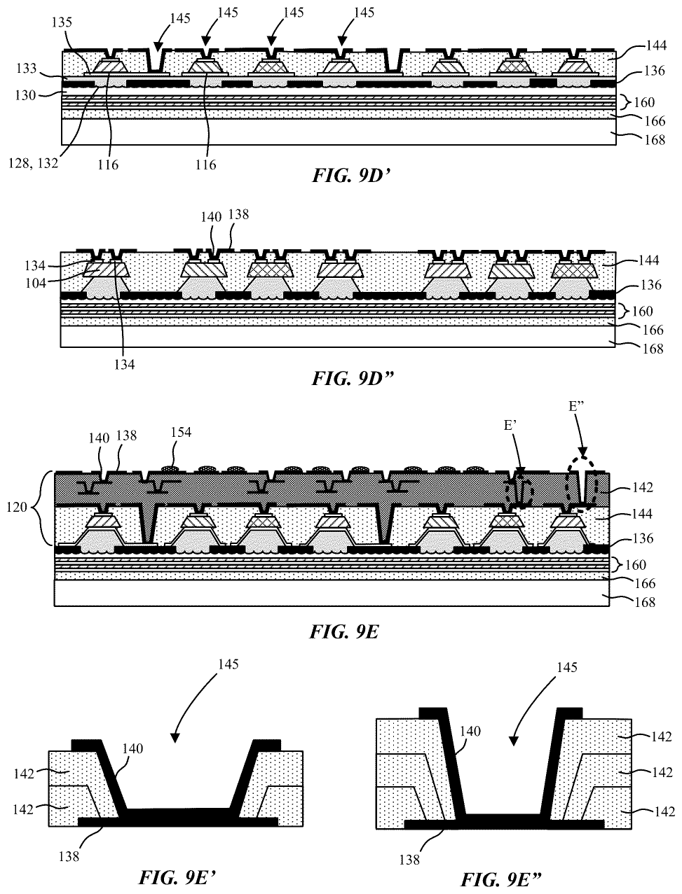

FIG. 7 illustrates a system diagram for an embodiment of a portable electronic device 700 including a display structure 110 described herein. The portable electronic device 700 includes a processor 720 and memory 740 for managing the system and executing instructions. The memory includes non-volatile memory, such as flash memory, and can additionally include volatile memory, such as static or dynamic random access memory (RAM). The memory 740 can additionally include a portion dedicated to read only memory (ROM) to store firmware and configuration utilities.

The system also includes a power module 780 (e.g., flexible batteries, wired or wireless charging circuits, etc.), a peripheral interface 708, and one or more external ports 790 (e.g., Universal Serial Bus (USB), HDMI, Display Port, and/or others). In one embodiment, the portable electronic device 700 includes a communication module 712 configured to interface with the one or more external ports 790. For example, the communication module 712 can include one or more transceivers functioning in accordance with IEEE standards, 3GPP standards, or other communication standards, 4G, 5G, etc. and configured to receive and transmit data via the one or more external ports 790. The communication module 712 can additionally include one or more

WWAN transceivers configured to communicate with a wide area network including one or more cellular towers, or base stations to communicatively connect the portable electronic device 700 to additional devices or components. Further, the communication module 712 can include one or more WLAN and/or WPAN transceivers configured to connect the portable electronic device 700 to local area networks and/or personal area networks, such as a Bluetooth network.

The portable electronic device 700 can further include a sensor controller 770 to manage input from one or more sensors such as, for example, proximity sensors, ambient light sensors, or infrared transceivers. In one embodiment the system includes an audio module 731 including one or more speakers 734 for audio output and one or more microphones 732 for receiving audio. In embodiments, the speaker 734 and the microphone 732 can be piezoelectric components. The portable electronic device 700 further includes an input/output (I/O) controller 722, a display structure 110, and additional I/O components 718 (e.g., keys, buttons, lights, LEDs, cursor control devices, haptic devices, and others). The display structure 110 and the additional I/O components 718 may be considered to form portions of a user interface (e.g., portions of the portable electronic device 700 associated with presenting information to the user and/or receiving inputs from the user).

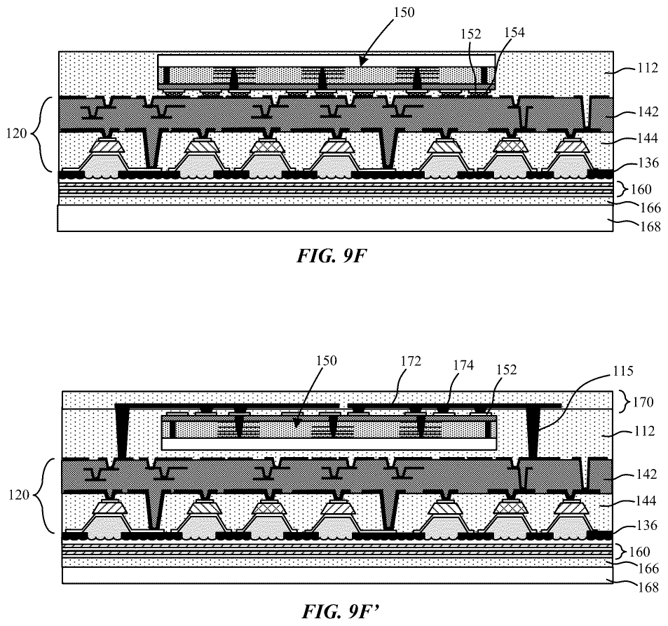

FIG. 8 is a schematic cross-sectional side view illustration of a portion of a display structure stack-up accordance with an embodiment. As shown, the display structure 110 may include an array of pixel driver chips 150 embedded in an insulation layer 112, a redistribution layer (RDL) 120 over and in electrical contact with the array of pixel driver chips 150, and an array of light emitting diodes (LEDs) 104 over and in electrical contact with the RDL 120. The array of LEDs may include multiple groups of LEDs designed for different color emission, such as red-emitting LEDs 104R, green-emitting LEDs 104G, and blue-emitting LEDs 104B for an RGB display. It is to be appreciated that this arrangement is exemplary, and different groups of LEDs may be selected. In the particular embodiment illustrated each of the LEDs for a first group of first LEDs designed for a first emission wavelength spectrum (e.g. red-emitting LEDs 104R), a second group of second LEDs designed for a second emission wavelength spectrum (e.g. green-emitting LEDs 104G), and a third group of third LEDs designed for a third emission wavelength spectrum (e.g. blue-emitting LEDs 104B) has a coplanar top surface. Specifically, the top surfaces 116G, 116R, 116B are all coplanar as indicated by the dashed line through FIG. 8.

While not required to achieve the coplanar surfaces, in some embodiments the top surfaces of the array of LEDs 104 are placed onto a corresponding array of transparent placement structures 122. Each transparent placement structure 122 can be a bank structure for example, including a bank bottom surface 124 onto which the LEDs 104 are placed, bank sidewalls 126, and a bank top surface 128. The bank sidewalls 126 may be straight sidewalls (e.g. vertical) or angled sidewalls as shown, which may aid in deposition of subsequent conformal layers. The bank top surface 128 may optionally be characterized by a greater surface roughness, such as average surface roughness (Ra), than the bank bottom surface 124 for the transparent placement structure 122. For example, this can be accomplished when forming the array of transparent placement structures 122 on an optional passivation layer 130, with the bank top surface 128 being conformal to a roughened bottom surface 132 of the passivation layer 130.

Generally, the LEDs in accordance with embodiments may be vertical micro LEDs including a p-n diode, a top surface 116 (top electrode side), a bottom contact 134 (bottom electrode side) and sidewall of the p-n diode. For example, the p-n diodes may be formed of inorganic semiconductor materials, such as III-V or II-VI materials. Exemplary materials include nitride-based semiconductors (e.g. GaN) and phosphorous-based semiconductors (e.g. AlInGaP, InGaP). Alternatively, the LEDs may be horizontal micro LEDs.

In the particular embodiment illustrated in FIG. 8 the LEDs 104 are vertical LEDs, with the RDL making electrical contact with the bottom contacts 134 of the LEDs. Top side electrical contact to the LEDs may be made with a transparent electrode layer 135 spanning over the array of transparent placement structures 122 such that the top surfaces 116 of the array of LEDs 104 are in electrical contact with the transparent electrode layer 135. The top surfaces 116 of the LEDs 104 may be placed directly onto the transparent electrode layer 135 spanning over the bottom surfaces 124 of the transparent placement structures 122. In such a configuration, the bank bottom surfaces 124 are also coplanar. The transparent electrode layer may further span along the bank sidewalls 126 of the transparent placement structures 122 and may be patterned to achieve various electrical connections between one or more LEDs.

The RDL 120 in accordance with embodiments may include a plurality of redistribution lines 138, contact via lines 140, and a plurality of interlayer dielectric (ILD) layers 142 separating the various metal layer levels of the redistribution lines 138. The RDL 120 may additionally include a dielectric layer 144, or passivation layer, that is formed around the array LEDs and the selective placement structures 122 to secure the LEDs in place. The dielectric layer 144 may be formed of a suitable insulating material, and may be formed using a suitable technique, such as slot coating, spin coating, vapor deposition, etc. in order to cover the array of LEDs and substantially fill the gaps therebetween. The ILD layers 142 may be formed of suitable materials including oxides (e.g. SiOx), nitrides, polymers, etc. The redistribution lines 138 and contact via lines 140 may be metallization layers such as copper, aluminum, etc. In accordance with embodiments, RDL 120 includes one or more of the plurality global signal lines and power lines. In the illustrated embodiments, the redistribution lines 138 and contact via lines 140 are formed using thin film techniques, and the contact via lines 140 may extend into via openings in the ILD layers 142 and dielectric layer 144. When utilizing thin film techniques, the contact via lines 140 may form an outline conforming to the via openings. Alternatively, other plating techniques can be utilized so that metal vias completely fill the via openings, though this may be accompanied by additional process operations, including metal planarization. In an embodiment, the plurality of contact via lines 140 extend through one or more ILD layers as shown in area B where a contact via line extends through at least two ILD layers 142, and as shown in area C where a contact via line extends through at least three ILD layers 142. The contact via lines 140 may also be used to make electrical contact with the transparent electrode layer 135 to make electrical contact with the top surfaces 116 of one or more LEDs 104.

Additional structures may be included such as, but not limited to, a distributed Bragg reflector (DBR) layer 160 over the optional passivation layer 130, lower passivation layer 166, and cover plate 168. For example, the DBR layer 160 may include alternating layers 162, 164 such as SiNx, SiOx, SiNx, SiOx. The layers of DBR layer 160 may also function as a passivation layer. Lower passivation layer 166 can additionally be formed of a transparent material. In some embodiments lower passivation layer 166 is formed of a transparent polymer material or glass that can be embossed to form a roughened bottom surface 132 for light extraction. Other materials, and roughening techniques may also be utilized. Cover plate 168 can also be formed of a transparent material such as glass.

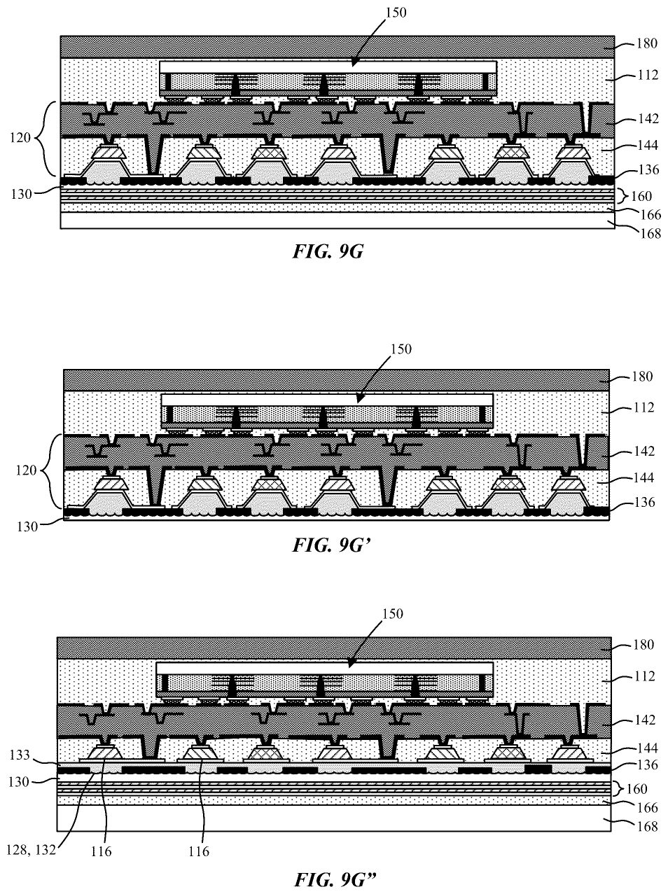

In the particular embodiment illustrated the pixel driver chips 150 are flip chip bonded with contact pads 152 facing the RDL 120. For example, the contact pads 152 may be bonded to the redistribution lines 138 (or landing pads formed therewith) using solder bumps 154. Alternatively, referring briefly to FIG. 9F′ the pixel driver chips can be mounted back side onto the RDL, with the front sides of the pixel driver chips including the contact pads 152 facing away from the RDL 120. In this manner, a plurality of vertical interconnects 115 can extend through the insulation layer 112 to electrically connect the pixel driver chips 150 with the RDL 120. Other variations to the process sequence or structural relationship of component are possible.

Referring now to FIGS. 9A-9G″, schematic cross-section side view illustrations are provided for a sequence of fabricating a display structure in accordance with an embodiment, along with a plurality of possible variations. As shown in FIG. 9A the process sequence can optionally begin with a cover plate 168, such as a transparent glass or polymer substrate, followed by lower passivation layer 166, such as a transparent glass, oxide, etc. and optional DBR layer 160. Together the lower passivation layer 166 and DBR layer 160 may enhance light extraction and viewing angle for the display structure to be formed. Passivation layer 130 may then be formed over the optional DBR layer 160. In an embodiment, the passivation layer 130 is patterned to include a roughened bottom surface 132 to facilitate light extraction. This may be accomplished for example by embossing or surface treatment with liquid or plasma. In an embodiment, the passivation layer 130 is formed of a transparent polymer, glass or oxide. A black matrix layer 136 can then be formed with openings 139 exposing the roughened bottom surface 132 of the passivation layer 130. This may control the optical apertures for light emission, and to block external light encroachment that could affect internal light reflection.

It is to be appreciated that while the example illustrated in FIG. 9A begins with the cover plate 168 that may be in the final display structure, the cover plate 168 can also be added later. Furthermore, cover plate 168 may be a thin layer backed by a more rigid carrier substrate at FIG. 9A that may be removed at a later stage, though can assist in processing.

Referring now to FIG. 9B, an array of selective placement structures 122 can be formed over the underlying structure. Specifically, the selective placement structures 122 can be formed over the openings 139 in the black matrix layer 136 and directly on top of the roughened bottom surface 132 of the passivation layer 130. The selective placement structures 122 may partially overlap the black matrix layer 136 between the openings 139. In accordance with embodiments the selective placement structures 122 may be formed of a transparent material, such as polymer, glass oxide. Exemplary polymer materials include acrylics such as poly (methyl methacrylate) (PMMA), benzocyclobutene (BCB), etc. As shown, each selective placement structure 122 can be in the form of a bank structure including a top surface 128 that conforms to the roughened bottom surface 132 of the passivation layer 130, sidewalls 126 and a bottom surface 124. The bottom surfaces 124 may be coplanar. Where vertical LED integration is to be included a transparent electrode layer 135 can be formed spanning over the bottom surfaces 124 of the transparent placement structures 122. The transparent electrode layer may further span along the bank sidewalls 126 of the transparent placement structures 122 and may be patterned to achieve various electrical connections between one or more LEDs. The transparent electrode layer 135 may be formed of various suitable transparent conductive oxides (TCOs) such as indium tin oxide (ITO), and conductive polymers.

The selective placement structures 122 in accordance with embodiments can enable a single-pick-multi-place transfer process. Referring now to FIG. 9C, a transfer tool 200 including an array of transfer heads 202 can pick up an array of LEDs from a donor substrate. In the exemplary embodiment illustrated multiple green-emitting LEDs 104 are picked up with multiple clusters of transfer heads. The selective placement structures 122 allow placement of select LEDs, while others are retained by the transfer heads. Such selective placement structures 122 can thus be integrated into the light extraction structure of the display structure to be formed, and also facilitate higher throughput of the transfer sequence, allowing multiple placements after a single pick up operation from a donor substrate.

Referring now to FIG. 9D, a partially fabricated structure is shown after transfer of the different groups of LEDs, including red-emitting LEDs 104R, blue-emitting LEDs 104B, and green-emitting LEDS 104G. As shown each group of LEDs may have a different thickness attributed to different inorganic semiconductor materials of fabrication, etc. Nevertheless, in the illustrated fabrication sequence the top surfaces of the different groups of LEDs can all be coplanar as shown with the dashed line. This can benefit Mura effect in the final display structure and can be considered a result of the “LED first” fabrication sequence.

Still referring to FIG. 9D, initial contact layers of the RDL 120 are formed. As shown, an initial dielectric layer 144 is formed over the array LEDs and around the selective placement structures 122. The dielectric layer 144 may be formed of a suitable insulating material, and may be formed using a suitable technique, such as slot coating, spin coating, vapor deposition, etc. in order to cover the array of LEDs and substantially fill the gaps therebetween. An optional planarization operation may then be performed followed by patterning to form via openings to expose the array of LEDs and the transparent top electrode layer 135. This may be followed by formation of the first metal layer, including redistribution lines 138 and contact via lines 140. As shown the via openings 145 may have different depths, depending upon LED thickness, and whether contact is made to a the bottom contacts 134 of the LEDs or transparent top electrode layer 135 (or intervening layer). Metal routing within the RDL 120, and around the LEDs, can also be tailored to increase light extraction, and reduce crosstalk between LEDs.

While the selective placement structures 122 in accordance with embodiments can be utilized to enhance placement throughput they are not required for the “LED first” integration sequence. In the variation illustrated in FIG. 9D′ the array of LEDs 104 can be placed directly onto a transparent top electrode layer 135, or alternatively a temporary adhesive layer that may be subsequently removed. In such an embodiment, the top surfaces of the LEDs can remain coplanar. The receiving structure at this point may additionally include pre-formed optical features, which can also be formed later. For example, the black matrix layer 136 can be formed before or after placement of the LEDs and can be formed at a much later fabrication operation where the LEDs are placed onto an adhesive layer on a temporary carrier. In the particular embodiment illustrated, an intermediate passivation layer 133 can be formed rather than the selective placement structures. As shown, the intermediate passivation layer 133 can be formed over the black matrix layer 136 and optional passivation layer 130, followed by planarization. As shown, the transparent top electrode layer 135 can be deposited over a planarized surface, which may include the intermediate passivation layer 133 and/or DBR layer 160. In turn, the transparent top electrode layer 135 then provides a planar surface for receiving the LEDs. A variety of configurations are possible.

Referring now to FIG. 9D″ another variation is illustrated in which LEDs with single-side contacts, also referred to as horizontal LEDs, are transferred to the receiving structure. Similar to the embodiments of FIG. 9 and FIG. 9D′ the receiving structure may optionally include the selective placement structures 122, where bottom side contacts 134 are included for both p-side and n-side contact of the LED. In this manner it is not required to form a top electrode layer, and the RDL can be utilized to provide all electrical connection to the LEDs. Similar to previous discussion, the horizontal LEDs may also have different thicknesses. The initial dielectric layer 144, via openings 145, and metallization layer can then be formed for the RDL. As shown, the RDL can include an array of contact via line 140 pairs in electrical contact with the bottom surfaces of the array of LEDs such that each contact via line 140 pair is in electrical contact with a corresponding LED.

The RDL 120 can then be completed as shown in FIG. 9E, followed by optional placement of solder bumps 154 onto landing pads of the redistribution lines 138. In accordance with some embodiments, routing complexity can be reduced, while providing space savings and use of less mask layers, by forming multiple level contact line vias that extend through a plurality of ILD layers 142. Specifically, FIG. 9E′ and FIG. 9E″ are close-up schematic cross-sectional side view illustrations of sections E′ and E″ of FIG. 9E. In the particular embodiment illustrated, a plurality of via openings 145 within a plurality of ILD layers 142 can overlap to form a single via opening 145 within which a contact via line 140 is formed.

Referring now to FIG. 9F, the array of pixel driver chips 150 can then be attached, for example with flip chip attachment onto solder bumps 154, followed by deposition of insulation layer 112 such that the pixel driver chips 150 are embedded within, and optional planarization. It is not required for the pixel driver chips 150 to be placed face side down with the contact pads 152 facing the RDL 120, and instead the pixel driver chips 150 may be placed back side down, or facing away the RDL 120 as shown in FIG. 9F′. In this variation the back side of the pixel driver chip 150 may be attached with an adhesive layer for example, followed by encapsulation within the insulation layer 112, and formation of back side routing 170 including wiring 172 and contact vias 174 used to make electrical contact with the contact pads 152. Furthermore, vertical interconnects 115 such as copper pillars or through dielectric vias may extend through the insulation layer to make electrical connection between the RDL 120 and the backside routing 170.

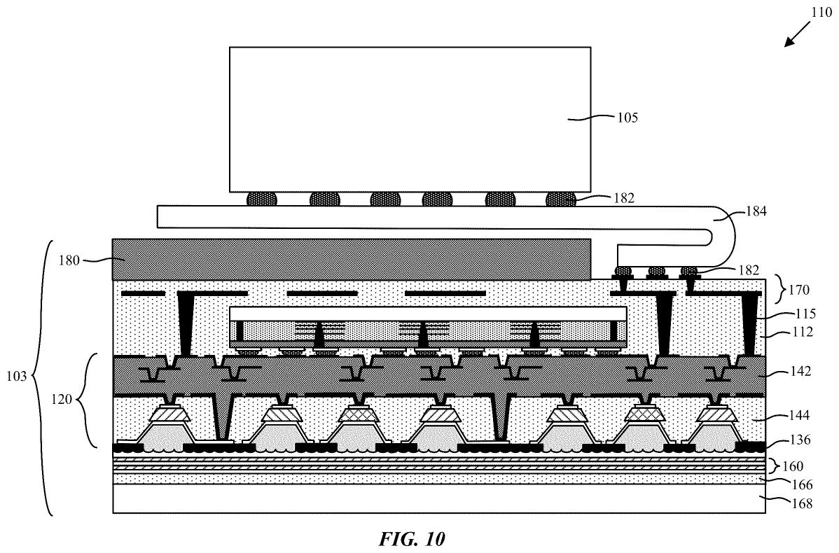

The back side routing 170 and vertical interconnects 115 illustrated in FIG. 9F′ may additionally be utilized to facilitate making external connection such as to control circuit 105 or other system components, for example with a flex circuit as described in more detail with regard to FIG. 10. Furthermore, the back side routing and vertical interconnects 115 can be included for either face down or face up placement of the pixel driver chips 150 depending upon electrical routing preference.

Following encapsulation of the pixel driver chips 150 and optional back side routing 170 a back side carrier substrate 180 can be formed. For example, a polymer or glass substrate can be attached with an adhesive to provide some structural integrity and protection from ambient.

Up until this point the fabrication sequences and variations described and illustrated have presumed the bottom side (front side) cover plate 168 and optics such as lower passivation layer 166 and DBR layer 160 are formed at the initial fabrication stages. In the variation illustrated in FIG. 9G′ it is shown that the passivation layer 130 could have initially been formed on a temporary carrier that is removed after attaching the back side carrier substrate 180. The optional DBR layer 160, lower passivation layer 166 and cover plate 168 can then be added toward the end of the fabrication sequence.

In yet another process variation, as shown in FIG. 9G″ the receiving structure can be a flat structure such as that previously illustrated and described with regard to FIG. 9D′ which can be processed similarly as other structures described herein after transfer of the LEDs.

The “LED first” fabrication sequences described herein can facilitate the fabrication of display structures with maximum display areas, and also allow for peripheral electronic components such as a display timing controller (TCON), which is typically located off panel, to be attached without using conventional chip on film (COF) techniques, therefore eliminating conventional bend tail further leading to potential border reduction. More specifically the peripheral electronic components can be integrated close in time with the pixel driver chips 150. Referring to FIG. 10, in the illustrated embodiment an external control circuit 105 can be attached to the back side of the display structure, and in electrical connection with the back side routing 170. The external control circuit 105 can be directly attached to the back side of the display structure, for example, with solder bumps 182, pins, etc. or be attached to a flex circuit 184, which in turn is also similarly attached to the back side of the display structure. While flex circuit 184 is illustrated as being bent, this is not required, and a variety of connection structures can be used. The illustrated flex circuit 184 can be double sided flex, printed circuit board (PCB), and may be hard board or a flexible circuit, etc. allowing removal of the bend. Other peripheral components can be similarly integrated. In the particular embodiment illustrated a partial back side carrier substrate 180 is shown, though this is also optional.

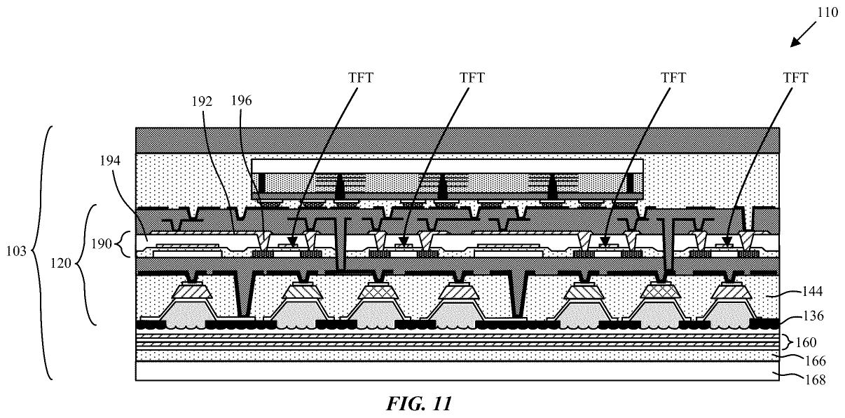

Referring now to FIG. 11 in an embodiment, the RDL may include a thin film transistor (TFT) layer 190 including an array of TFTs coupled with the array of LEDs and the array of pixel driver chips to form a hybrid TFT and pixel driver chip architecture where the TFT layer 190 can be fabricated prior to the pixel driver chip integration, removing a thermal budget constraint for TFT fabrication. In such a configuration the pixel driver chips may provide digital functionality with the TFT layer including local subpixel circuitry to provide analog functionality, for example.

Any of the plurality of global signal lines and power lines may also, or alternatively, be formed in the TFT layer 190. In an embodiment, the TFT layer 190 is used primarily for local routing. The TFT layer 190 may include an array of TFTs, capacitors, and electrical routing. For example, the TFTs may be silicon or oxide transistors. For example, the array of TFTs may include both low temperature polycrystalline silicon (LTPS) TFTs and oxide TFTs. Similar to RDL 120, the TFT layer 190 may additionally include a plurality of metal routing lines 192 and dielectric layers 194. Routing lines 192 (or vias 196 thereof) may contact the source/drains of the TFTs.

In operation, the pixel driver chips may update with multiplexing and row sharing, while a mostly passive TFT layer 190 is set to the LED driving current value and is always on until it is reprogrammed. This may enable digital driving at higher multiplexing ratios than possible with local passive matrix addressing, and with reduced power consumption and complexity of active matrix addressing.

In utilizing the various aspects of the embodiments, it would become apparent to one skilled in the art that combinations or variations of the above embodiments are possible for forming a bottom emission display structure with an “LED first” fabrication sequence. Although the embodiments have been described in language specific to structural features and/or methodological acts, it is to be understood that the appended claims are not necessarily limited to the specific features or acts described. The specific features and acts disclosed are instead to be understood as embodiments of the claims useful for illustration.

What is claimed is:

1. A display structure comprising:
an array of pixel driver chips embedded in an insulation layer;
a redistribution layer (RDL) over and in electrical contact with the array of pixel driver chips;
an array of light emitting diodes (LEDs) over and in electrical contact with the RDL, wherein the array of LEDs includes:
a first group of first LEDs designed for a first wavelength emission spectrum, each first LED including a first top surface; and
a second group of second LEDs designed for a second wavelength emission spectrum different from the first wavelength emission spectrum, each second LEDs including a second top surface;
wherein each first top surface is coplanar with each second top surface.

2. The display structure of claim 1:
further comprising an array of transparent placement structures onto which top surfaces of the array of LEDs are placed;
wherein each transparent placement structure is a bank structure including a bank bottom, surface bank sidewalls, and a bank top surface; and
wherein the top surfaces of the array of LEDs includes the first top surfaces and the second top surfaces.

3. The display structure of claim 2, wherein the bank top surface is characterized by a greater surface roughness than the bank bottom surface for each transparent placement structure.

4. The display structure of claim 3, wherein the array of transparent placement structures is formed on a passivation layer, wherein the bank top surface for each transparent placement structure is conformal to a roughened bottom surface of the passivation layer.

5. The display structure of claim 2, further comprising a transparent electrode layer spanning over the array of transparent placement structures, wherein the top surfaces of the array of LEDs are in electrical contact with the transparent electrode layer.

6. The display structure of claim 5, and the transparent electrode layer spans over the bank bottom surface and the bank sidewalls of each transparent placement structure.

7. The display structure of claim 6, wherein the bank bottom surface of each transparent placement structure is coplanar.

8. The display structure of claim 2, wherein the RDL includes an array of contact via line pairs in electrical contact with the bottom surfaces of the array of LEDs such that each contact via line pair is in electrical contact with a corresponding LED.

9. The display structure of claim 1, wherein the first LEDs are thicker than the second LEDs.

10. The display structure of claim 1, wherein each pixel driver chip is bonded to the RDL with a plurality of solder bumps.

11. The display structure of claim 1, wherein each pixel driver chip includes a front side with a plurality of contact pads facing away from the RDL.

12. The display structure of claim 11, further comprising a plurality of vertical interconnects extending through an insulation layer, and electrically connecting the array of pixel driver chips with the RDL.

13. The display structure of claim 1, wherein the RDL includes an array of thin film transistors (TFTs) coupled with the array of LEDs and the array of pixel driver chips.

14. The display structure of claim 13, wherein the array of TFTs includes low temperature polycrystalline silicon (LTPS) TFTs and oxide TFTs.

15. The display structure of claim 1, wherein:
the RDL includes a plurality of wiring layers forming a plurality of redistribution lines and a plurality of contact via lines, and a plurality of interlayer dielectric (ILD) layers separating levels of redistribution lines of the plurality of redistribution lines; and
the plurality of contact via lines extend through one or more ILD layers of the plurality of ILD layers.

16. The display structure of claim 15, wherein the plurality of contact via lines includes a first group of contact via lines extending through a thickness of at least two ILD layers.

17. The display structure of claim 15, wherein the plurality of contact via lines includes a first group of contact via lines extending through a thickness of at least three ILD layers.

18. The display structure of claim 15, wherein the contact via lines extend through via openings through the one or more ILD layers, and form an outline conforming to the via openings.
